(19) United States
(12) Patent Application Publication
(10) Pub. No.: US 2024/0162376 A1
(43) Pub. Date: May 16, 2024

(54) LIGHT-EMITTING DEVICE AND DISPLAY DEVICE

(71) Applicant: KYOCERA Corporation, Kyoto-shi, Kyoto (JP)

(72) Inventors: Kazuhiro NISHIDA, Nagahama-shi, Shiga (JP); Masaya TAMAKI, Yokohama-shi, Kanagawa (JP)

(21) Appl. No.: 18/282,196

(22) PCT Filed: Mar. 2, 2022
(86) PCT No.: PCT/JP2022/008745

§ 371 Date: Sep. 14, 2023

(30) Foreign Application Priority Data
Mar. 15, 2021 (JP) 2021-041779

(51) Int. Cl. H01L 33/10; H01L 25/075

(52) U.S. Cl. CPC H01L 33/105; H01L 25/0753

(57) ABSTRACT

A light-emitting device includes a first substrate including a first surface, a second substrate including a second surface facing the first surface, a third surface opposite to the second surface, and a through-hole extending from the second surface to the third surface, and a light emitter located on a portion of the first surface exposed in the through-hole in a plan view. The light emitter emits light having a maximum radiant intensity in a radiant intensity distribution toward the third surface. The through-hole reflects the light having the maximum radiant intensity twice or more times on an inner peripheral surface of the through-hole. The light emitting device includes a space between the first surface and the second surface.

### TECHNICAL FIELD

The present disclosure relates to a light-emitting device and a display device.

### BACKGROUND OF INVENTION

A known light-emitting device is described in, for example, Patent Literature 1.

### CITATION LIST

### Patent Literature

Patent Literature 1: Japanese Unexamined Patent Application Publication No. 2013-8941

### SUMMARY

In an aspect of the present disclosure, a light-emitting device includes a first substrate including a first surface, a second substrate including a second surface facing the first surface, a third surface opposite to the second surface, and a through-hole extending from the second surface to the third surface, and a light emitter located on a portion of the first surface exposed in the through-hole. The light emitter emits light having a maximum radiant intensity in a radiant intensity distribution toward the third surface. The through-hole is configured to reflect the light having the maximum radiant intensity two or more times on an inner peripheral surface of the through-hole. The first surface and the second surface are separated by a space.

In another aspect of the present disclosure, a display device includes the above light-emitting device. The display device includes a matrix of a plurality of through-holes.

### BRIEF DESCRIPTION OF THE DRAWINGS

The objects, features, and advantages of the present disclosure will become more apparent from the following detailed description and the drawings.

FIG. 1 is a plan view of a light-emitting device according to one embodiment of the present disclosure.

FIG. 2 is a cross-sectional view taken along line A1-A2 in FIG. 1.

FIG. 3 is a graph showing the angular distribution of radiant intensity of light emitted from a light-emitting diode (LED).

FIG. 4 is a cross-sectional view of a light-emitting device according to a variation of the embodiment of the present disclosure.

FIG. 5 is a cross-sectional view of a light-emitting device according to a variation of the embodiment of the present disclosure.

FIG. 6 is a cross-sectional view of a light-emitting device according to a variation of the embodiment of the present disclosure.

FIG. 7 is a plan view of a display device according to one embodiment of the present disclosure.

FIG. 8 is a cross-sectional view taken along line B1-B2 in FIG. 7.

FIG. 9 is a graph showing the simulation results of the light intensity at the front of a light-emitting device.

FIG. 10 is a graph showing the simulation results of the light intensity at the front of a light-emitting device.

FIG. 11 is a graph showing the simulation results of the light intensity at the front of a light-emitting device.

FIG. 12 is a graph showing the simulation results of the light intensity at the front of a light-emitting device.

FIG. 13 is a cross-sectional view of a light-emitting device according to a variation of the embodiment of the present disclosure.

FIG. 14 is a cross-sectional view of a light-emitting device according to a variation of the embodiment of the present disclosure.

### DESCRIPTION OF EMBODIMENTS

The structure that forms the basis of a light-emitting device according to one or more embodiments of the present disclosure will be described. Patent Literature 1 describes a light-emitting device including a light emitter and a frame-shaped reflective member surrounding the light emitter located on one main surface of a substrate. The light emitter such as a light-emitting diode (LED) may have light distribution characteristics with which the angular distribution of radiant intensity of light is not the highest in a direction perpendicular to the light-emitting surface. A known light-emitting device including a light emitter with such light distribution characteristics may have low directivity of emission light.

The light-emitting device and a display device according to one or more embodiments of the present disclosure will now be described with reference to the accompanying drawings. Each figure referred to below illustrates main components and other elements of the light-emitting device and the display device according to one or more embodiments of the present disclosure. The light-emitting device and the display device according to the embodiments of the present disclosure may include known components not illustrated in the figures, such as circuit boards, wiring conductors, control ICs, and LSI circuits. The figures referred to below are schematic, and may not be drawn to scale relative to, for example, the actual positions and dimensional ratios of components of the light-emitting device and the display device.

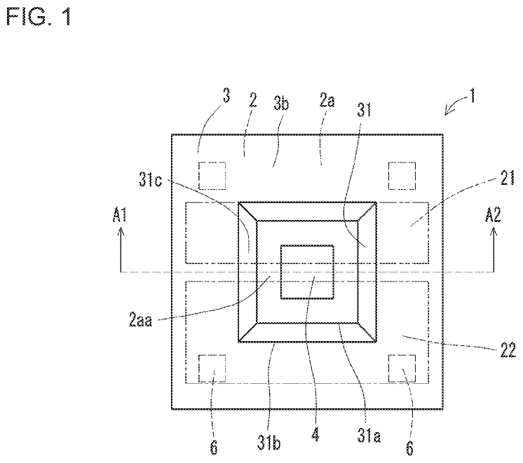

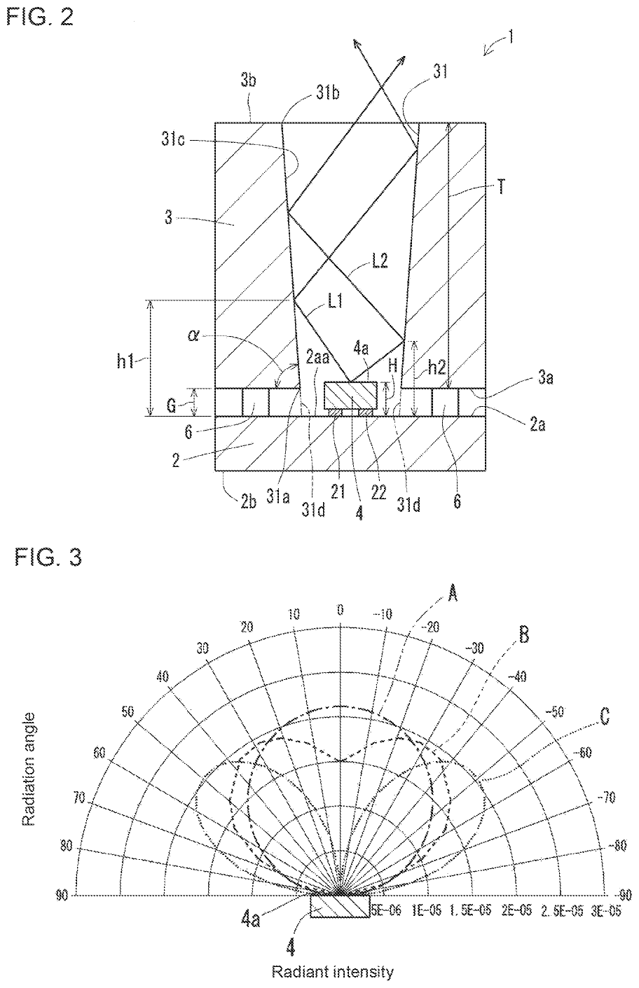

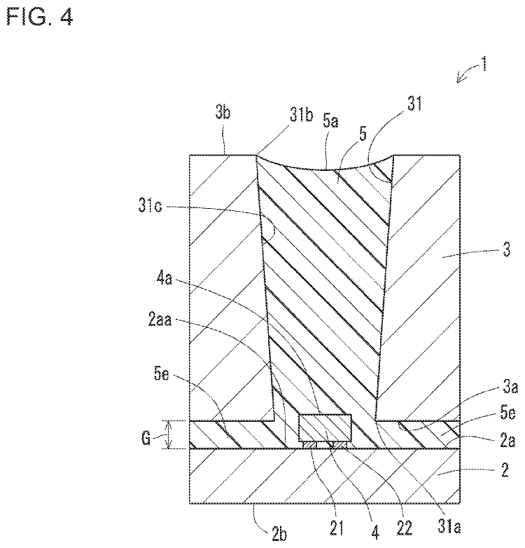

FIG. 1 is a plan view of a light-emitting device according to one embodiment of the present disclosure. FIG. 2 is a cross-sectional view taken along line A1-A2 in FIG. 1. FIG. 3 is a graph showing the angular distribution of radiant intensity of light emitted from an LED. FIG. 3 shows three examples of radiant intensity (W/sr: watts per steradian) distribution patterns of light emitted from an LED. FIGS. 4 to 6 are cross-sectional views of a light-emitting device according to a variation of the embodiment of the present disclosure. The cross-sectional views of FIGS. 4 to 6 correspond to the cross-sectional view of FIG. 2.

A light-emitting device 1 according to the present embodiment includes a first substrate 2, a second substrate 3, and a light emitter 4. The light-emitting device 1 includes the first substrate 2, the second substrate 3 located on the first substrate 2 and including a through-hole 31 extending through in the thickness direction, and the light emitter 4 located on a portion 2aa of the first substrate 2, which is exposed in the through-hole 31, to emit light having the maximum radiant intensity (also referred to as maximum intensity light) in the radiant intensity distribution in a direction inclined upward (inclined toward the opening of the through-hole 31). The through-hole 31 reflects the maximum intensity light twice or more times on an inner peripheral surface 31c. A space G (illustrated in FIG. 2) is between the first substrate 2 and the second substrate 3. More specifically, the light-emitting device 1 includes the first substrate 2 with a first surface 2a, the second substrate 3 with a second surface 3a facing the first surface 2a, a third surface 3b opposite to the second surface 3a, and the through-hole 31 extending from the second surface 3a to the third surface 3b, and the light emitter 4 located on the portion 2aa of the first surface 2a exposed in the through-hole 31 to emit the maximum intensity light in the radiant intensity distribution toward the third surface 3b. The through-hole 31 reflects the maximum intensity light twice or more times on the inner peripheral surface 31c. The space G is between the first surface 2a and the second surface 3a.

The light-emitting device 1 with the above structure produces the effects described below. The space G between the first surface 2a and the second surface 3a can increase the depth of the through-hole 31. This increases the number of times the maximum intensity light emitted from the light emitter 4 is reflected on the inner peripheral surface 31c of the through-hole 31, and increases the directivity of emission light from the light-emitting device 1.

The first substrate 2 includes the first surface (also referred to as one main surface) 2a and the other main surface 2b. The first substrate 2 may be, for example, triangular, square, rectangular, trapezoidal, polygonal such as hexagonal, circular, oval, or in any other shape in a plan view (as viewed in a direction perpendicular to the first surface 2a).

The first substrate 2 is made of, for example, a glass material, a ceramic material, a resin material, a metal material, or a semiconductor material. Examples of the glass material used for the first substrate 2 include borosilicate glass, crystallized glass, and quartz. Examples of the ceramic material used for the first substrate 2 include alumina (Al₂O₃), zirconia (ZrO₂), silicon nitride (Si₃N₄), silicon carbide (SiC), and aluminum nitride (AlN). Examples of the resin material used for the first substrate 2 may include an epoxy resin, a polyimide resin, a polyamide resin, a polycarbonate resin, and an acrylic resin.

Examples of the metal material used for the first substrate 2 include aluminum (Al), titanium (Ti), beryllium (Be), magnesium (Mg) (specifically, high-purity magnesium with a Mg content of 99.95% or higher), zinc (Zn), tin (Sn), copper (Cu), iron (Fe), chromium (Cr), nickel (Ni), and silver (Ag). Examples of an alloy material used for the first substrate 2 include duralumin, which is an aluminum alloy containing aluminum as a main component (an Al—Cu alloy, an Al—Cu—Mg alloy, or an Al—Zn—Mg—Cu alloy), a magnesium alloy containing magnesium as a main component (a Mg—Al alloy, a Mg—Zn alloy, or a Mg—Al—Zn alloy), titanium boride, stainless steel, and a Cu—Zn alloy. Examples of the semiconductor materials used for the first substrate 2 include silicon, germanium, and gallium arsenide.

The first substrate 2 may include a drive circuit for controlling, for example, the emission or non-emission state and the light intensity of the light emitter 4. The drive circuit includes, for example, a thin-film transistor (TFT) and a wiring conductor. The TFT may include a semiconductor film of, for example, amorphous silicon (a-Si) or low-temperature polycrystalline silicon (LTPS), and three terminals that are a gate electrode, a source electrode, and a drain electrode. The TFT serves as a switching element that switches conduction and non-conduction between the source electrode and the drain electrode based on the voltage applied to the gate electrode.

The drive circuit may be located on one main surface 2a of the first substrate 2, or may be located on one main surface 2a and the other main surface 2b. The drive circuit may be between multiple insulating layers of, for example, silicon oxide (SiO₂) or silicon nitride (Si₃N₄) located on one main surface 2a. The drive circuit may be formed by a thin film formation method such as chemical vapor deposition (CVD). When the first substrate 2 is made of a glass material, the drive circuit may include a TFT with a semiconductor film made of LTPS. The drive circuit can be formed directly on the first substrate 2 using a thin film formation method such as CVD.

The second substrate 3 includes the second surface (one main surface) 3a and the third surface (the other main surface) 3b opposite to the second surface 3a. The second surface 3a faces the first surface 2a of the first substrate 2. The third surface 3b is exposed outside the light-emitting device 1 and is also referred to as a light-emitting surface or a display surface. The second substrate 3 may be, for example, triangular, square, rectangular, trapezoidal, polygonal such as hexagonal, circular, oval, or in any other shape in a plan view.

The first substrate 2 and the second substrate 3 may have the same outer shape in a plan view. The first substrate 2 and the second substrate 3 may be equilateral triangular, square, or equilateral hexagonal in a plan view. This facilitates joining (tiling) of multiple light-emitting devices 1 into a composite display device.

The second substrate 3 is made of, for example, a glass material, a ceramic material, a resin material, a metal material, or a semiconductor material. Examples of the glass material used for the second substrate 3 include borosilicate glass, crystallized glass, and quartz. Examples of the ceramic material used for the second substrate 3 include alumina, zirconia, silicon nitride, silicon carbide, and aluminum nitride. Examples of the resin material used for the second substrate 3 include an epoxy resin, a polyimide resin, a polyamide resin, a polycarbonate resin, and an acrylic resin. Examples of the metal material used for the second substrate 3 include A1, Ti, Be, Mg (specifically, high-purity magnesium with a Mg content of 99.95% or higher), Zn, Sn, Cu, Fe, Cr, Ni, Ag, molybdenum (Mo), and tungsten (W). Examples of an alloy material used for the second substrate 3 include duralumin, which is an aluminum alloy containing aluminum as a main component (an Al—Cu alloy, an Al—Cu—Mg alloy, or an Al—Zn—Mg—Cu alloy), a magnesium alloy containing magnesium as a main component (a Mg—Al alloy, a Mg—Zn alloy, or a Mg—Al—Zn alloy), titanium boride, stainless steel, and a Cu—Zn alloy. Examples of the semiconductor material used for the second substrate 3 include silicon, germanium, and gallium arsenide.

The second substrate 3 may include a single layer of the glass material, the ceramic material, the resin material, the metal material, or the semiconductor material described above, or may be a stack of multiple layers of the glass material, the ceramic material, the resin material, the metal material, or the semiconductor material described above that are stacked on one another. For the second substrate 3 made of a metal material, an insulating layer of, for example, silicon oxide (SiO₂) or silicon nitride (Si₃N₄) or an insulating member made of a resin material may be located between the first substrate 2 and the second substrate 3.

The second substrate 3 includes the through-hole 31 extending from the second surface 3a to the third surface 3b in the thickness direction. The through-hole 31 includes a first opening 31a in the second surface 3a and a second opening 31b in the third surface 3b. As illustrated in, for example, FIGS. 1 and 2, the second opening 31b may have a larger opening area than the first opening 31a. As illustrated in, for example, FIG. 1, the outer edge of the second opening 31b may surround the outer edge of the first opening 31a. As illustrated in, for example, FIGS. 1 and 2, the through-hole 31 may have a section parallel to the third surface 3b being gradually smaller in the direction from the third surface 3b toward the second surface 3a.

The first opening 31a may be, for example, triangular, square, rectangular, circular, oval, or in any other shape in a plan view. The second opening 31b may be, for example, triangular, square, rectangular, circular, oval, or in any other shape in a plan view. The first opening 31a and the second opening 31b may or may not have a similar shape.

For the second substrate 3 made of a glass material, the through-hole 31 may be formed by, for example, photolithography. For the second substrate 3 made of a ceramic material, a powder of a raw ceramic material is mixed with an appropriate organic binder and an appropriate solvent to form slurry. The slurry is then shaped into a sheet using a known method such as doctor blading or calendering to form a ceramic green sheet (hereafter also referred to as a green sheet). The green sheet is then punched into a predetermined shape including a hole to be the through-hole 31. The second substrate 3 including a through-hole 31 can be fabricated by stacking multiple punched green sheets and firing them together at a temperature of about 1600° C. For the second substrate 3 made of a resin material, the second substrate 3 including the through-hole 31 can be fabricated by, for example, injection molding. For the second substrate 3 made of a metal material, the second substrate 3 including the through-hole 31 can be fabricated by, for example, punching or electroforming (plating). For the second substrate 3 made of a semiconductor material, the second substrate 3 including the through-hole 31 can be fabricated by, for example, dry etching.

In the present embodiment, as illustrated in, for example, FIG. 2, the light-emitting device 1 includes the space G between the first surface 2a of the first substrate 2 and the second surface 3a of the second substrate 3. The space G may be determined based on, for example, the dimensions of the light emitter 4, the radiant intensity distribution of the light emitter 4, and the shape of the through-hole 31. The space G may be determined based on the front intensity of the light-emitting device 1. The space G may be 0 to about 10 μm inclusive, or 0 to about 5 μm inclusive.

The first substrate 2 includes the portion 2aa (also referred to as an element mount) of the first surface 2a exposed in the through-hole 31 in a plan view. The light emitter 4 is located on the element mount 2aa of the first substrate 2. The light emitter 4 is located on the element mount 2aa and thus includes a light-emitting surface 4a exposed to the second opening 31b. The light emitter 4 emits light having the maximum radiant intensity in the radiant intensity distribution toward the third surface 3b.

The light emitter 4 may be, for example, a self-luminous element such as an LED, an organic LED (OLED), or a semiconductor laser diode (LD). In the present embodiment, the light emitter 4 is an LED. The light emitters 4 may be micro-LEDs. The light emitter 4 being a micro-LED located on the element mount 2aa may be rectangular in a plan view with each side having a length of about 1 to 100 μm inclusive or about 5 to 20 μm inclusive. The light emitter 4 may have a height of 2 to 10 μm inclusive from the element mount 2aa of the light-emitting surface 4a.

The light-emitting device 1 includes an anode electrode 21 and a cathode electrode 22 located on the element mounts 2aa of the first substrate 2. The anode electrode 21 is electrically connected to an anode terminal of the light emitter 4. The cathode electrode 22 is electrically connected to a cathode terminal of the light emitter 4. The anode electrode 21 and the cathode electrode 22 are electrically connected to a drive circuit for controlling, for example, the emission or non-emission state and the light intensity of the light emitter 4.

The light emitter 4 may be electrically and mechanically connected to the anode electrode 21 and the cathode electrode 22 by, for example, flip-chip connection using a conductive connector, such as an anisotropic conductive film (ACF), a solder ball, a metal bump, or a conductive adhesive. The light emitter 4 may be electrically connected to the anode electrode 21 and the cathode electrode 22 using conductive connectors such as bonding wires. For the first substrate 2 made of a metal material or a semiconductor material, the insulating layer of, for example, silicon oxide (SiO₂) or silicon nitride (Si₃N₄) may be located at least on the first surface 2a of the first substrate 2. The light emitter 4 may be located on the insulating layer. This reduces electrical short-circuiting between the anode terminal and the cathode terminal of the light emitter 4.

For the light emitter 4 being an LED, the directivity of radiant intensity may be low, as indicated by, for example, radiant intensity distribution patterns A, B, and C in FIG. 3. In the radiant intensity distribution of the light emitter 4, the radiant intensity may not be maximum in a direction frontward from the light-emitting surface 4a (upward in FIG. 2) as in the radiant intensity distribution patterns B and C. More specifically, the radiant intensity distribution patterns B and C include light having the maximum radiant intensity that is emitted by the light emitter 4 at an incline with respect to the direction perpendicular to the first surface 2a. The inventors have noticed that, for the light emitter 4 with radiant intensity distribution pattern A, B, or C, or in particular, the radiant intensity distribution pattern B or C, the directivity of emission light from the light-emitting device 1 is reduced when most of the emission light from the light emitter 4 is emitted outside after no reflection or after reflecting once on the inner peripheral surface 31c of the through-hole 31. The inventors have also noticed that the directivity of emission light from the light-emitting device 1 increases when most emission light (e.g., 40 to 60% of the total amount of emission light) from the light emitter 4, with the radiant intensity distribution pattern B or C, is emitted outside after reflecting on the inner peripheral surface 31c twice or more times. A range of values referred to herein as one value to another value intends to mean the two values being inclusive.

In the light-emitting device 1 according to the present embodiment, the through-hole 31 allows light L1 having the maximum radiant intensity in the radiant intensity distribution to be reflected twice or more times on the inner peripheral surface 31c. This also increases the directivity of light emitted from the light-emitting device 1.

In the present embodiment, the light-emitting device 1 includes the space G between the first substrate 2 and the second substrate 3. For the light emitter 4 being an LED, as shown in, for example, FIG. 3, the intensity of light emitted in the direction of the radiation angle θ is low at the angle of about 900 to the vertical line of the light-emitting surface 4a of the light emitter 4. With the space G between the first substrate 2 and the second substrate 3, less light leaks outside through the gap between the first substrate 2 and the second substrate 3 and does not substantially reduce the amount of light reflected on the inner peripheral surface 31c of the through-hole 31. The space G between the first substrate 2 and the second substrate 3 increases the distance between the first surface 2a and the third surface 3b. In other words, the space G can increase the depth of the through-hole 31. The through-hole 31 can reflect the maximum intensity light with the radiation angle θ of about an angle θ MAX as well as at least a part of the light other than the maximum intensity light with the radiation angle θ other than the angle θ MAX twice or more times on the inner peripheral surface 31c. The angle θ MAX refers to the radiation angle of the maximum intensity light in the radiant intensity distribution of the light emitter 4.

As described above, the light-emitting device 1 according to the present embodiment can reflect the maximum intensity light with the radiation angle θ of about the angle θ MAX as well as at least a part of light other than the maximum intensity light with the radiation angle θ other than the angle θ MAX twice or more times on the inner peripheral surface 31c of the through-hole 31. The directivity of the light emitted from the light-emitting device can be increased effectively.

In the light-emitting device 1, the radiant intensity distribution of light emitted outside through each through-hole 31 (more specifically, the light emitted from the light-emitting device 1 outside) can be a highly directional pattern with a longitudinally oblong shape approximate to a cosine (cos θ) surface, with the maximum intensity direction substantially aligned with a normal to the display surface 3b. The radiant intensity distribution of light emitted outside through the through-hole 31 has a highly directional pattern of a longitudinally oblong shape approximate to a cosine surface, which follows Lambert's cosine law (the law by which the radiant intensity of light observed from an ideal diffuse radiator is directly proportional to the cosine of the angle θ between the direction of the incident light and the normal of the radiating surface, or the display surface 3b of the light-emitting device 1). The cosine surface herein refers to a radiant intensity distribution pattern of light in the shape of a cosine curve as viewed in a longitudinal section.

The light-emitting device 1 can have front intensity (light intensity measured at the front of the light-emitting device 1) about 2 to 9 times more than the front intensity achieved by a light-emitting device without the second substrate 3.

An angle θ1 (also referred to as a main emission angle) defined as the angle including at least 50% of the total amount of emission light in the radiant intensity distribution of the light emitted outside through the through-hole 31 in the light-emitting device 1 may be less than or equal to a predetermined angle. The predetermined angle may depend on the radiant intensity distribution of the light emitter 4. The predetermined angle may be, for example, about 30°, about 20°, or about 10°. The angle θ1 occurs when the direction orthogonal to the light-emitting surface 4a (as illustrated in FIG. 3) of the light emitter 4 is 0°.

In the light-emitting device 1, the first substrate 2 and the second substrate 3 define a cavity (recess) to accommodate the light emitter 4. With the space G, the cavity is defined by the first surface 2a, the inner peripheral surface 31c, and an imaginary inner peripheral surface 31d as an imaginary extension surface of the inner peripheral surface 31c toward the first surface 2a. This cavity has a larger volume than a cavity defined by the first surface 2a of the first substrate 2 and the inner peripheral surface 31c of the through-hole 31 when no space G is included. In the light-emitting device 1, this cavity with a relatively large volume can accommodate, for example, quantum dots, wavelength conversion materials such as phosphors, and color filters. This increases the degree of freedom in designing the light-emitting device 1 by, for example, causing the light-emitting device 1 to have a radiation spectrum different from the radiation spectrum of the light emitter 4.

The first substrate 2 and the second substrate 3 may be bonded together with an adhesive. The light-emitting device 1 can have, in the space G between the first substrate 2 and the second substrate 3, a sufficient amount of the adhesive to firmly bond the first substrate 2 and the second substrate 3. The light-emitting device 1 has higher reliability. Examples of the adhesive to bond the first substrate 2 and the second substrate 3 together include transparent resin adhesives, such as an epoxy resin, and transparent resins that are adhesive, such as an acrylic resin, a polycarbonate resin, and a silicone resin. The adhesive may contain a light-absorbing material. The light-absorbing material may be, for example, an inorganic pigment. Examples of the inorganic pigment may include carbon pigments such as carbon black, nitride pigments such as titanium black, and metal oxide pigments such as Cr—Fe—Co, Cu—Co—Mn, Fe—Co—Mn, and Fe—Co—Ni—Cr pigments. The light-absorbing material may be an insulating material such as a metal oxide pigment. This prevents short-circuiting of wiring, electrode pads, and other conductive parts on the first surface 2a of the first substrate 2 through the light-absorbing material.

The light-emitting device 1 may include a spacer 6 as a space retainer, forming the space G between the first substrate 2 and the second substrate 3, as illustrated in, for example, FIGS. 1 and 2. In this case, the relative positions of the first substrate 2 and the second substrate 3 in the light-emitting device 1 are stable. The space G is unlikely to vary under external forces. The light-emitting device 1 thus has high directivity of the emission light and long-term reliability. The spacer 6 may be annular in a plan view, continuously or intermittently surrounding the element mount 2aa and the light emitter 4. Multiple spacers 6 may be spaced apart from one another, as illustrated in, for example, FIGS. 1 and 2. Each spacer 6 may be a columnar shape such as a cylinder or a square prism, or a frustum such as a conical frustum or a square frustum. The drive circuit on the first surface 2a of the first substrate 2, or the wiring conductors connecting the drive circuit to the anode electrode and the cathode electrode, may form a part of the spacer 6.

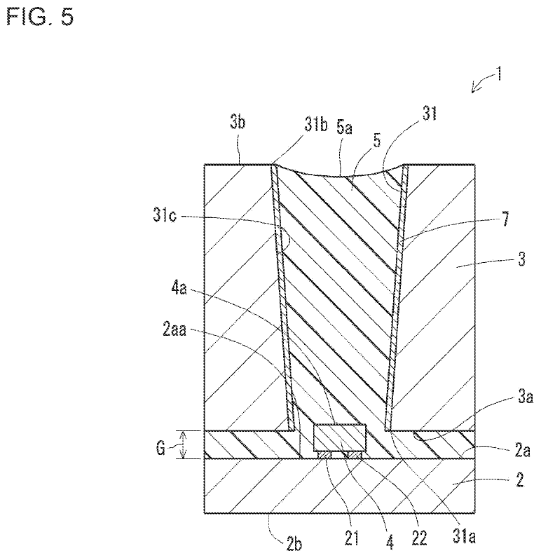

The spacer 6 may reflect light. In this case, light entering the space G can be reflected toward the through-hole 31, thus increasing the light utilization efficiency. Light entering the space G is less likely to travel toward the adjacent through-holes 31. The spacer 6 may be made of the same or similar metal material as a light-reflective layer 7 (illustrated in FIG. 5). The spacer 6 may be made of, for example, a metal material such as Al, Ag, gold (Au), Cr, Ni, platinum (Pt), or Sn. The spacer 6 may be made of the same or similar metal material as the anode electrode 21 and the cathode electrode 22. For example, the spacer 6 may include a conductor layer of tantalum (Ta), W, Ti, Mo, Al, Cr, Ag, Cu, or Ni. The spacer 6 may be made of, for example, Al, Al/Ti, Ti/Al/Ti, Mo, Mo/Al/Mo, Ti/Al/Mo, Mo/Al/Ti, Cu, Cr, Ni, or Ag. Al indicates a single layer of an Al layer, and Ti/Al/Ti indicates a stack of multiple layers with an Al layer on a Ti layer and a Ti layer on the Al layer. The same applies to other notations.

The spacer 6 may absorb light. In this case, light entering the space G can be absorbed by the spacer 6. Light entering the space G is less likely to travel toward the adjacent through-holes 31. The spacer 6 may be made of a photo-curing or a thermosetting resin material (e.g., an epoxy resin, a silicone resin, or an acrylic resin) containing a light-absorbing material. The resin material may be applied to the first surface 2a of the first substrate 2 and cured. The light-absorbing material may be, for example, an inorganic pigment. Examples of the inorganic pigment may include carbon pigments such as carbon black, nitride pigments such as titanium black, and metal oxide pigments such as Cr—Fe—Co, Cu—Co—Mn, Fe—Co—Mn, and Fe—Co—Ni—Cr pigments. The spacer 6 may include a rough surface that absorbs incident light. For example, the spacer 6 may be a black layer of a base material such as a silicone resin mixed with black particles such as carbon black. The display surface of the black layer may include a rough surface. The rough surface may have an arithmetic mean roughness of about 10 to 50 μm or about 20 to 30 μm. The black layer may have a surface roughness appropriate for the mean particle size or the mean radius of the black particles.

As illustrated in FIG. 2, for example, the space G may be less than a height h1, which is the height from the first surface 2a to the first reflection point of the light L1 having the maximum radiant intensity on the inner peripheral surface 31c of the through-hole 31. As shown in FIG. 3, for example, light with the radiation angle θ slightly larger or slightly smaller than the angle θ MAX may have substantially the same level of radiant intensity as the maximum intensity light. In other words, the radiation angle θ MAX of the maximum intensity light may allow a certain degree of variation (Δθ MAX). The space G less than the height h1 can reduce the likelihood that the maximum intensity light having the radiation angle θ within the range of the angle Δθ MAX leaks outside through the space G between the first substrate 2 and the second substrate 3. The space G less than the height h1 can allow the maximum intensity light having the radiation angle θ within the range of the angle Δθ MAX to be reflected twice or more times on the inner peripheral surface 31c of the through-hole 31. The light-emitting device 1 can have high directivity of the emission light with high luminance. The angle Δθ MAX may be in the range of 27 to 370 for the radiant intensity distribution pattern B, and 47 to 530 for the radiant intensity distribution pattern C, but is not limited to these ranges.

As illustrated in FIG. 2, for example, a height h2 is the height from the first surface 2a of the substrate 2 to the first reflection point of light L2, with half the intensity of the maximum radiant intensity on the inner peripheral surface 31c of the through-hole 31. The height h2 may be less than the height h1, and the space G may be less than the height h2. This structure effectively reduces the ratio of the amount of light leaking outside through the gap between the first substrate 2 and the second substrate 3 out of the total amount of emission light from the light emitter 4. Most of the emission light from the light emitter 4 (e.g., 40 to 60% of the total amount of emission light) can be reflected twice or more times on the inner peripheral surface 31c of the through-hole 31. The light-emitting device 1 can have higher directivity of the emission light with higher luminance.

For example, the height h1 is about 44 to 122 μm inclusive, and the height h2 is about 17 to 18 μm inclusive. These heights h1 and h2 are not limited to these ranges.

The second substrate 3 may include a larger opening in the third surface 3b than in the second surface 3a of the through-hole 31. The inclination angle of the inner peripheral surface 31c of the through-hole 31 with respect to the element mount 2aa may be about 70 to 850 inclusive. The second substrate 3 may have a thickness T of about 30 to 100 μm inclusive. The light emitted from the light emitter 4 and reflected on the inner peripheral surface 31c of the through-hole 31 can easily move toward the inner peripheral surface 31c of the through-hole 31 again, thus increasing the amount of light reflected twice or more times on the inner peripheral surface 31c of the through-hole 31. This increases the amount of light emitted from the light-emitting device 1 in directions less than or equal to the main emission angle θ1, thus further increasing the directivity of the light emitted from the light-emitting device 1. The inclination angle may be, for example, an angle α between the element mount 2aa and the inner peripheral surface 31c of the through-hole 31 as viewed in a longitudinal section of the light-emitting device 1 (refer to FIG. 2). The longitudinal section may be, for example, a section of the light-emitting device 1 cut along a line including the centroid of the element mount 2aa and perpendicular to the first surface 2a of the substrate 2. When the angle α varies depending on the longitudinal section, the minimum value of the angle α in the longitudinal sections taken in varied manners may be defined as the inclination angle. The inclination angle may be the angle between the normal of the element mount 2aa and the normal of the inner peripheral surface 31c.

As illustrated in FIG. 13, the through-hole 31 may include the opening in the third surface 3b (second opening 31b) smaller than the opening in the second surface 3a (first opening 31a). Although the thickness T of the second substrate 3 (corresponding to the depth of the through-hole 31) is smaller than in the configuration illustrated in FIG. 2, the light L1 having the maximum radiant intensity can be reflected twice or more times on the inner peripheral surface 31c of the through-hole 31. This increases the degree of convergence of light emitted outside through the through-hole 31. The angle α may be about 95 to 110°, but the ranges are not limited to this range.

The light-emitting device 1 may include a light-transmissive seal 5 in the through-hole 31 as illustrated in FIG. 4. The seal 5 may be located on the element mount 2aa of the first surface 2a of the substrate 2 and inside the through-hole 31 to cover the light emitter 4. The seal 5 may have insulating properties and may directly cover the light emitter 4. This reduces the likelihood of the light emitter 4 being misaligned or separate from the element mount 2aa, thus increasing the reliability of the light-emitting device 1.

The seal 5 is made of, for example, a resin material. Examples of the resin material used for the seal 5 include a silicone resin, an acrylic resin, a polycarbonate resin, and an epoxy resin. The seal 5 may contain light-scattering particles made of, for example, a glass material. The seal 5 may be formed by placing the above resin material in the through-hole 31 and curing the material by, for example, a photo-curing method of irradiating the material with light such as ultraviolet rays, a thermal curing method of curing the material at a predetermined temperature, or a photothermal curing method. The seal 5 may be made of a glass material. In this case, the seal 5, which is shaped to fit into the through-hole 31, may be placed in the through-hole 31 and bonded to the inner peripheral surface 31c with a transparent adhesive.

The seal 5 may include, as illustrated in FIG. 4 for example, an extension 5e between the first surface 2a of the first substrate 2 and the second surface 3a of the second substrate 3. In this case, the first substrate 2 and the second substrate 3 are bonded stronger. This prevents, for example, misalignment or separation between the substrates over time. The seal 5 may be made of a transparent resin that is adhesive and may bond the first substrate 2 and the second substrate 3 together.

The seal 5 includes a front surface 5a exposed outside, which may be flat or curved convexly outward. The front surface 5a of the seal 5 may be, as illustrated in FIG. 4 for example, curved concavely outward. The front surface 5a of the seal 5 may have an optical function to focus or collimate the light passing through the seal 5. This also effectively increases the directivity of light emitted from the light-emitting device 1.

In the second substrate 3, the inner peripheral surface 31c of the through-hole 31 may reflect light. For example, the inner peripheral surface 31c of the through-hole 31 may include a mirror surface. This reduces the likelihood of the amount of reflected light decreasing when at least part of light emitted from the light emitter 4 is reflected on the inner peripheral surface 31c of the through-hole 31 twice or more times. This reduces the likelihood that the amount of light emitted outside through the through-hole 31 decreases.

For the second substrate 3 made of a material with low light reflectivity, such as a glass material, a ceramic material, or a resin material, as illustrated in FIG. 5 for example, a light-reflective layer 7 may be located on the inner peripheral surface 31c of the through-hole 31.

The light-reflective layer 7 may include a metal layer with high light reflectance of visible light that may be made of a metal material such as Al, Ag, Au, Cr, Ni, Pt, or Sn. The light-reflective layer 7 may include an alloy layer made of an alloy material with high light reflectance of visible light such as duralumin (an Al—Cu alloy, an Al—Cu—Mg alloy, or an Al—Zn—Mg—Cu alloy), which is an aluminum alloy mainly containing aluminum. Such metal materials and alloy materials have a light reflectance of about 90 to 95% for aluminum, 93% for silver, 60 to 70% for gold, 60 to 70% for chromium, 60 to 70% for nickel, 60 to 70% for platinum, 60 to 70% for tin, and 80 to 85% for an aluminum alloy.

The light-reflective layer 7 may be formed by a thin film formation method such as CVD, vapor deposition, or plating on the inner peripheral surface 31c of the through-hole 31. The light-reflective layer 7 may be formed by a film formation method such as a thick film formation method in which a resin paste containing particles of the metal material or the alloy material is fired and solidified on the inner peripheral surface 31c of the through-hole 31. The light-reflective layer 7 may be formed by a bonding method of bonding a film of the metal material or the alloy material onto the inner peripheral surface 31c of the through-hole 31.

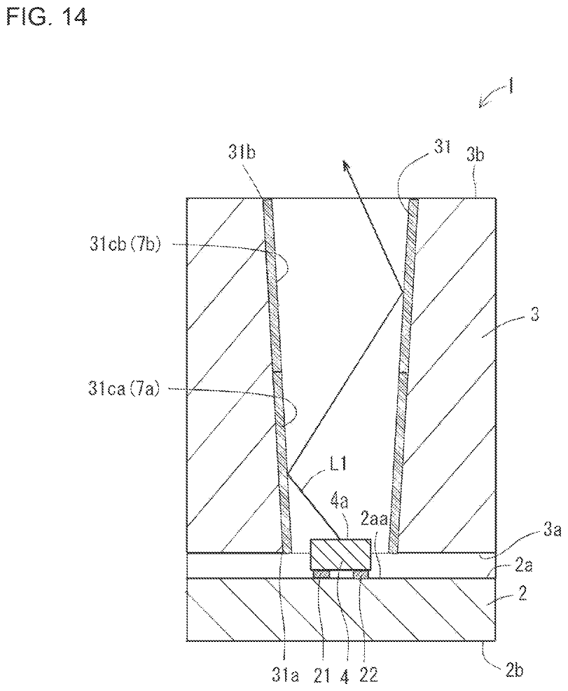

As illustrated in FIG. 14, the inner peripheral surface 31c of the through-hole 31 may reflect more light on a portion closer to the third surface 3b (a portion 31cb) than on a portion closer to the second surface 3a (a portion 31ca). For example, a light-reflective layer 7b located on the portion 31cb may have higher reflectance than a light-reflective layer 7a on the portion 31ca. This effectively reduces the decrease in intensity of reflected light at second and subsequent reflections of the light L1 with the maximum radiant intensity.

For example, the light-reflective layer 7a and the light-reflective layer 7b may be made of different materials. The material of the light-reflective layer 7a may be made of, for example, silver (reflectance of about 93%) or an aluminum alloy (reflectance of about 80 to 85%). The material of the light-reflective layer 7b may be made of aluminum (reflectance of about 90 to 95%). The light-reflective layer 7a and the light-reflective layer 7b may be different in surface roughness. The light-reflective layer 7a may have a greater arithmetic mean roughness than the light-reflective layer 7b. More specifically, the light-reflective layer 7a has greater absorptivity and greater scattering of incident light than the light-reflective layer 7b. The light-reflective layer 7a may have an arithmetic mean roughness of about 100 nm to 10 μm. The light-reflective layer 7b may have an arithmetic mean roughness of about 1 nm to 100 nm. A surface with a surface roughness of 1/10 or less with respect to the optical wavelength of 550 nm, to which the human eye is most sensitive, is optically a mirror surface. D The light-reflective layer 7a may thus have an arithmetic mean roughness of about 55 nm to 10 μm. The light-reflective layer 7b may have an arithmetic mean roughness of about 1 nm to 55 nm.

The ratio of the portion 31ca to the area of the inner peripheral surface 31c of the through-hole 31 may be about 30 to 70%. The ratio of the portion 31cb may be about 70 to 30%. The ratios are not limited to these ranges.

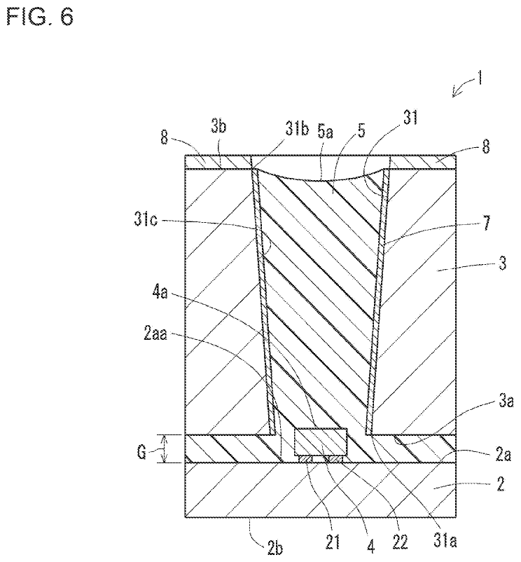

As illustrated in, for example, FIG. 6, the light-emitting device 1 may include a light-absorbing layer 8 on the third surface 3b of the second substrate 3. In this case, external light is reflected on the third surface 3b of the second substrate 3. This reduces interference of the external light with light emitted through the through-hole 31 outside. The light-emitting device can thus have high light emission quality with reduced susceptibility to external light.

The light-absorbing layer 8 is formed by, for example, applying a photo-curing or a thermosetting resin material containing a light-absorbing material to the third surface 3b and curing the material. The light-absorbing material may be, for example, an inorganic pigment. Examples of the inorganic pigment include a carbon pigment such as carbon black, a nitride pigment such as titanium black, and a metal oxide pigment such as a chromium-iron-cobalt (Cr—Fe—Co) pigment, a copper-cobalt-manganese (Cu—Co—Mn) pigment, an iron-cobalt-manganese (Fe—Co—Mn) pigment, or an iron-cobalt-nickel-chromium (Fe—Co—Ni—Cr) pigment.

The light-absorbing layer 8 may include a rough surface that absorbs incident light. For example, the light-absorbing layer 8 may be a black film of a base material such as a silicone resin mixed with a black pigment such as carbon black. A rough surface may be on the outer surface of the black layer. The rough surface may be formed by, for example, transferring. The rough surface may have an arithmetic mean roughness of about 10 to 50 μm or about 20 to 30 μm. This structure greatly increases light absorption.

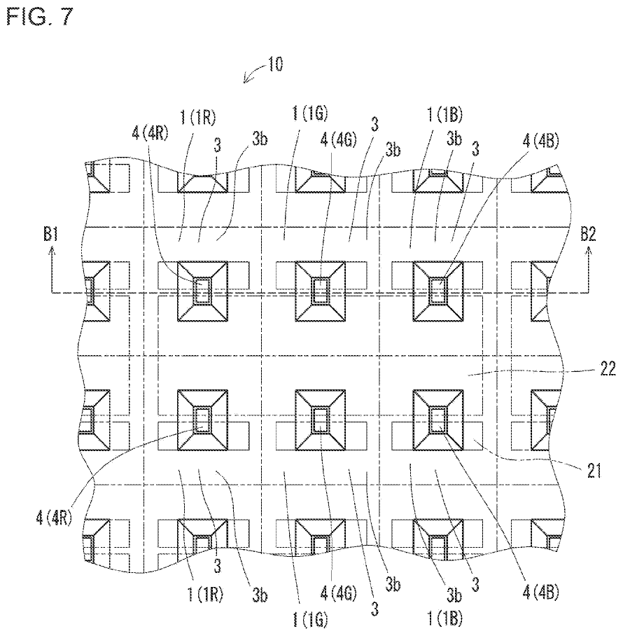

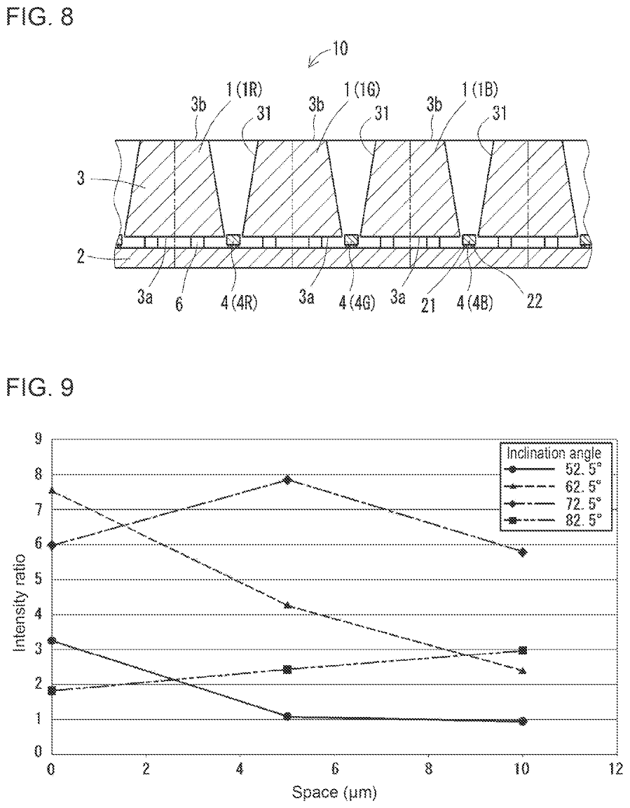

A display device according to one embodiment of the present disclosure will now be described. FIG. 7 is a plan view of a display device according to one embodiment of the present disclosure. FIG. 8 is a cross-sectional view taken along line B1-B2 in FIG. 7.

In one or more embodiments of the present disclosure, a display device 10 includes the light-emitting device 1 including a matrix of multiple through-holes 31. The display device 10 may include a single first substrate 2 and a single second substrate 3 including a matrix of multiple through-holes 31, or may include a matrix of multiple light-emitting devices 1.

The display device 10 according to the present embodiment includes, as illustrated in FIGS. 7 and 8 for example, multiple light-emitting devices 1. The light-emitting devices 1 are arranged in a matrix in a single plane to form a composite display device (multi-display). The light-emitting devices 1 may be arranged with multiple display surfaces 3b in a single imaginary plane. The light-emitting devices 1 may be joined (tiled) to each other by joining the sides of every two adjacent light-emitting devices 1 with a bond such as an inorganic adhesive or an organic adhesive. The bond may be a mechanical joining member such as a screw. The light-emitting devices 1 may be installed on a base substrate.

The display device 10 may include the first substrate 2 and the second substrate 3 integral with each other in multiple light-emitting devices 1. More specifically, the display device 10 may include multiple light emitters 4 on the first surface 2a of a single first substrate 2, and multiple through-holes 31 in a single second substrate 3 accommodating the respective light emitters 4. The display device 10 may include multiple cathode electrodes 22 of the light-emitting devices 1 that are integral with one another as a common cathode electrode.

The display device 10 may include multiple pixel units. Each pixel unit may include multiple light-emitting devices 1. The light-emitting devices 1 included in each pixel unit may be, as illustrated in FIGS. 7 and 8 for example, a light-emitting device 1R incorporating a light emitter 4R that emits red light, a light-emitting device 1G incorporating a light emitter 4G that emits green light, and a light-emitting device 1B incorporating a light emitter 4B that emits blue light. This allows the display device 10 to display full-color gradation.

Each pixel unit may include, in addition to the above light-emitting devices 1R, 1G, and 1B, at least one of a light-emitting device 1 that emits yellow light or a light-emitting device 1 that emits white light. This improves the color rendering and color reproduction of the display device 10. Each pixel unit may include, in place of the light-emitting device 1R that emits red light, a light-emitting device 1 that emits orange, red-orange, red-violet, or violet light. Each pixel unit may include, in place of the light-emitting device 1G that emits green light, a light-emitting device 1 that emits yellow-green light.

The display device 10 includes multiple light-emitting devices 1 with increased directivity of the emission light. High intensity emission light from each of multiple pixel units mixes moderately with high intensity emission light from other pixel units. The display device 10 includes improved image quality, such as luminance, contrast, gradation, and color rendering.

### EXAMPLES

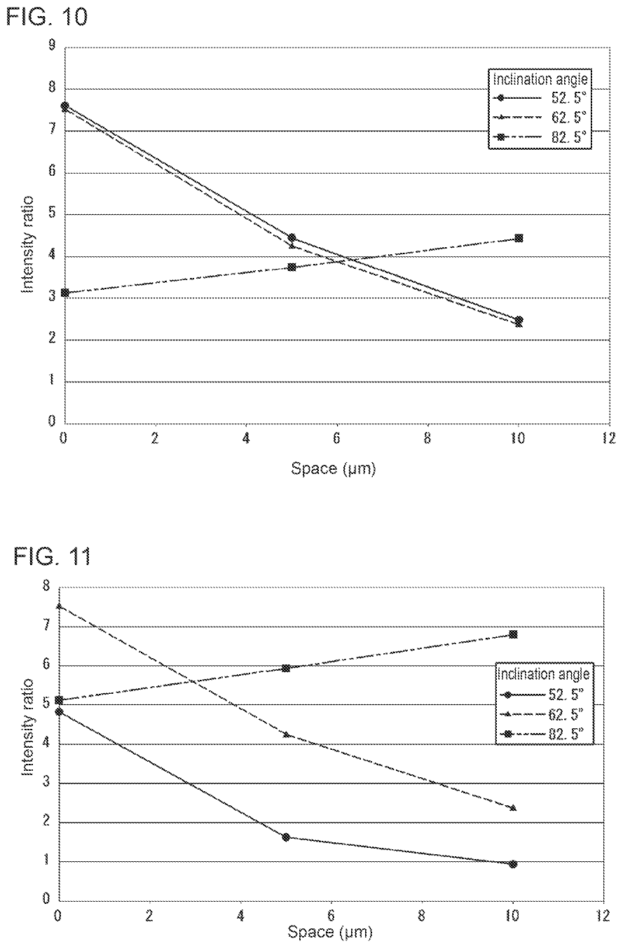

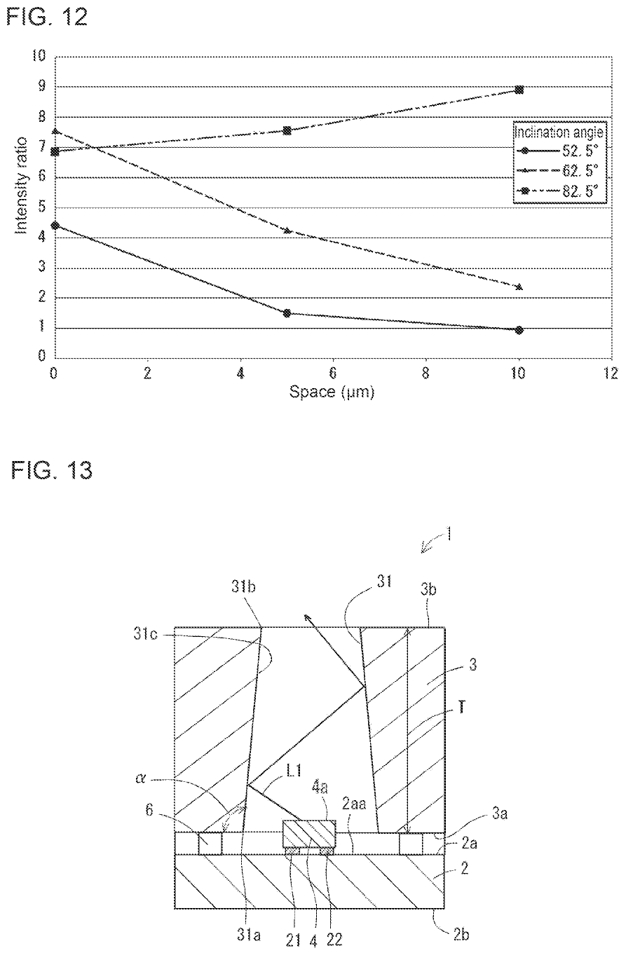

For the light-emitting device 1 illustrated in FIGS. 1 and 2, the light intensity at the front of the display surface 3b was calculated by simulation in one example. This simulation was performed for multiple light-emitting devices 1 that each differ in the thickness of the second substrate 3 (corresponding to the depth of the through-hole 31) and the inclination angle of the inner peripheral surface 31c of the through-hole 31 with respect to the first surface 2a. The graphs in FIGS. 9 to 12 show the simulation results. FIG. 9 shows the results for the through-hole 31 with a depth of 30 μm. FIG. 10 shows the results for the through-hole 31 with a depth of 50 μm. FIG. 11 shows the results for the through-hole 31 with a depth of 80 μm. FIG. 12 shows the results for the through-hole 31 with a depth of 100 μm. Each light-emitting device 1 includes the first substrate 2 and the second substrate 3 that are glass substrates, and the through-hole 31 including the light-reflective layer 7 on the inner peripheral surface 31c.

The second substrate 3 has a longitudinal length of 24 μm (in the vertical direction in FIG. 1) and a horizontal length of 24 μm (in the lateral direction in FIG. 1) for the first opening 31a in the through-hole 31 in a plan view. The inner peripheral surface 31c of the through-hole 31 has a light reflectance of 96%. The light emitter 4 has a longitudinal length of 20 μm and a horizontal length of 20 μm. The light-emitting surface 4a has a height H of 3 μm from the first surface 2a. The light emitter 4 has the radiant intensity distribution pattern B shown in FIG. 3.

FIGS. 9 to 12 are graphs showing the simulation results of the light intensity at the front of a light-emitting device 1. FIGS. 9 to 12 each show an intensity ratio I/I0 of front intensity I in the light-emitting device 1 to front intensity I0 achieved by a light-emitting device without the second substrate 3. FIGS. 9 to 12 each show the dependence of the intensity ratio I/I0 on the space G. FIGS. 9 to 12 correspond to the simulation results of the intensity ratio I/I0 when the thickness T (corresponding to the depth of the through-hole 31) of the second substrate 3 is set to 30 μm, 50 μm, 80 μm, and 100 μm, respectively.

Of the simulation results shown in FIGS. 9 to 12, the intensity ratio I/I0 with the space G greater than 0 μm greater than the intensity ratio I/I0 with the space G of 0 am indicates that the space G has increased the directivity of the light-emitting device 1. As shown in FIGS. 9 to 12, when the inner peripheral surface 31c of the through-hole 31 has an inclination angle of 72.5° or 82.5° with respect to the first surface 2a, the intensity ratio I/I0 can be increased by increasing the space G to greater than 0 μm. When the inner peripheral surface 31c of the through-hole 31 has a relatively large inclination angle, increasing the space G to greater than 0 μm can increase the amount of light emitted from the light emitter 4 and reflected on the inner peripheral surface 31c twice or more times, with a small amount of light leaking toward the space G. In other words, the space G increases the depth (a portion that contributes to increasing the number of reflections) of the through-hole 31. This also increases the directivity of light emitted from the light-emitting device 1.

As shown in FIG. 9, the intensity ratio I/I0 decreases when the inner peripheral surface 31c of the through-hole 31 has an inclination angle of 72.5° and the space G is greater than about m. This decrease may occur when the intensity of the light leaking outside through the space G between the first substrate 2 and the second substrate 3 exceeds the intensity of the light reflected twice or more times on the inner peripheral surface 31c of the through-hole 31 and emitted in the front direction of the light-emitting device 1. When the inner peripheral surface 31c of the through-hole 31 has an inclination angle of 52.5° or 62.5° with respect to the first surface 2a, the intensity ratio I/I0 decreases by increasing the space G to greater than 0 μm. This decrease may occur when the inclination angle of the inner peripheral surface 31c of the through-hole 31 is relatively small, and the light emitted from the light emitter 4 reflects once on the inner peripheral surface 31c of the through-hole 31 and moves outside without being reflected again, and is unlikely to be reflected twice or more times on the inner peripheral surface 31c.

The space G greater than 0 μm can increase the directivity of the light emitted from the light-emitting device 1. The display device can have improved image quality, such as luminance, contrast, gradation, and color rendering.

With the through-hole 31 including the inner peripheral surface 31c with an inclination angle of as large as 82.5°, the intensity ratio I/I0 is higher as the through-hole 31 is deeper, although the space G is small. As the space G increases, the intensity ratio I/I0 increases further. As shown in, for example, FIG. 11 (the structure with the depth of the through-hole 31 of 80 μm), when the space G is about 0 to 3 μm, and the inclination angle of the inner peripheral surface 31c of the through-hole 31 is 82.5°, the intensity ratio I/I0 is slightly lower than when the inclination angle is 62.5°. However, with the space G of about 3 μm or greater, the intensity ratio I/I0 is higher when the inclination angle of the inner peripheral surface 31c of the through-hole 31 is 82.5° than when the inclination angle is 62.5°. As the space G increases, the intensity ratio I/I0 increases further. As shown in FIG. 12 (the structure with the depth of the through-hole 31 of 100 μm), when the inclination angle of the inner peripheral surface 31c of the through-hole 31 is 82.5° and the space G is about 0 μm, the intensity ratio I/I0 is slightly lower than the intensity ratio I/I0 with the inclination angle of 62.5°. However, with the space G is about 1 μm or greater, the intensity ratio I/I0 is higher when the inclination angle of the inner peripheral surface 31c of the through-hole 31 is 82.5° than when the inclination angle is 62.5°. As the space G increases, the intensity ratio I/I0 increases further.

As shown in FIGS. 11 and 12, the opening in the third surface 3b may be larger than the opening in the second surface 3a of the through-hole 31, the depth of the through-hole 31 may be 80 μm or greater, the inclination angle of the inner peripheral surface 31c of the through-hole 31 may be 82.5° or greater, and the space G may be 3 μm or greater.

In the light-emitting device according to one or more embodiments of the present disclosure, the space between the first surface and the second surface can increase the depth of the through-hole. This increases the number of times the light having a maximum radiant intensity emitted from the light emitter is reflected on the inner peripheral surface of the through-hole, and increases the directivity of emission light from the light-emitting device. The display device according to one or more embodiments of the present disclosure further improves image quality, such as luminance, contrast, gradation, and color rendering.

Although the embodiments of the present disclosure have been described in detail, the present disclosure is not limited to the embodiments described above, and may be changed or varied in various manners without departing from the spirit and scope of the present disclosure. The components described in the above embodiments may be entirely or partially combined as appropriate unless any contradiction arises.

### INDUSTRIAL APPLICABILITY

The light-emitting device and the display device according to one or more embodiments of the present disclosure may be used for various electronic devices. Such electronic devices include lighting apparatus, automobile route guidance systems (car navigation systems), ship route guidance systems, aircraft route guidance systems, indicators for instruments in vehicles such as automobiles, instrument panels, smartphones, mobile phones, tablets, personal digital assistants (PDAs), video cameras, digital still cameras, electronic organizers, electronic books, electronic dictionaries, personal computers, copiers, terminals for game devices, television sets, product display tags, price display tags, programmable display devices for industrial use, car audio systems, digital audio players, facsimile machines, printers, automatic teller machines (ATMs), vending machines, medical display devices, digital display watches, smartwatches, guidance display devices installed in stations or airports, and signage (digital signage) for advertisement.

### REFERENCE SIGNS

1, 1R, 1G, 1B light-emitting device
2 first substrate
2a first surface (one main surface)
2aa portion (element mount)
2b other main surface
21 anode electrode
22 cathode electrode
3 second substrate
3a second surface
3b third surface (display surface)
31 through-hole
31a first opening
31b second opening
31c inner peripheral surface
31ca, 31cb portion
31d imaginary inner peripheral surface
4, 4R, 4G, 4B light emitter
4a light-emitting surface
5 seal
5a front surface
5e extension
6 space retainer (spacer)
7, 7a, 7b light-reflective layer
8 light-absorbing layer
10 display device

1. A light-emitting device, comprising:
a first substrate including a first surface;
a second substrate including a second surface facing the first surface, a third surface opposite to the second surface, and a through-hole extending from the second surface to the third surface; and
a light emitter located on a portion of the first surface exposed in the through-hole, the light emitter being configured to emit light having a maximum radiant intensity in a radiant intensity distribution toward the third surface,
wherein the through-hole is configured to reflect the light having the maximum radiant intensity two or more times on an inner peripheral surface of the through-hole, and
the first surface and the second surface are separated by a space.

2. The light-emitting device according to claim 1, wherein
the light having the maximum radiant intensity is emitted by the light emitter at an incline with respect to a direction perpendicular to the first surface.

3. The light-emitting device according to claim 1 wherein
the space is less than a height h1 from the first surface to a first reflection point of the light having the maximum radiant intensity on the inner peripheral surface.

4. The light-emitting device according to claim 3, wherein
the space is less than a height h2 from the first surface to a first reflection point of light having half an intensity of the maximum radiant intensity on the inner peripheral surface, and the height h2 is less than the height h1.

5. The light-emitting device according to claim 1, wherein
the through-hole includes an opening in the third surface that is larger than an opening in the second surface, and has a depth of 80 μm or greater, and
the inner peripheral surface has an inclination angle of 82.5° or greater with respect to the first surface.

6. The light-emitting device according to claim 1 wherein the through-hole includes an opening in the third surface that is smaller than an opening in the second surface.

7. The light-emitting device according to claim 1 wherein the through-hole includes a light-transmissive seal that seals the light emitter.

8. The light-emitting device according to claim 7, wherein
the light-transmissive seal includes an extension extending between the first surface and the second surface.

9. The light-emitting device according to claim 1 further comprising:
a space retainer between the first surface and the second surface.

10. The light-emitting device according to claim 9, wherein
the space retainer reflects light.

11. The light-emitting device according to claim 9, wherein
the space retainer absorbs light.

12. The light-emitting device according to claim 9 wherein
the space retainer surrounds the light emitter in a plan view.

13. The light-emitting device according to claim 1 wherein
the inner peripheral surface of the through-hole reflects light.

14. The light-emitting device according to claim 13, wherein
the inner peripheral surface of the through-hole reflects more light on a portion closer to the third surface than on a portion closer to the second surface.

15. The light-emitting device according to claim 1 wherein
the light emitter includes a micro-light-emitting diode.

16. A display device, comprising:
the light-emitting device according to claim 1,
wherein the display device includes a matrix of a plurality of through-holes.
